(19) United States
(12) Patent Application Publication
(10) Pub. No.: US 2009/0260689 A1
(43) Pub. Date: Oct. 22, 2009

(54) Solar cell lead wire, method of making the same, and solar cell

(75) Inventors: Hajime Nishi, Hitachi (JP); Yuju Endo, Hitachi (JP); Hiroyuki Akutsu, Hitachi (JP); Hiroshi Okikawa, Hitachi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: Hitachi Cable, Ltd., Tokyo (JP); Hitachi Cable Fine Tech, Ltd., Hitachi-shi (JP)

(21) Appl. No.: 12/385,417

(22) Filed: Apr. 7, 2009

(30) Foreign Application Priority Data
Feb. 13, 2008 (JP) 2008-31658
Nov. 11, 2008 (JP) 2008-288813

(51) Int. Cl. H01L 31/00; H01B 5/00; B21D 31/00

(52) U.S. Cl. 136/261; 174/126.1; 72/364

(57) ABSTRACT

A solar cell lead wire includes a conducting material, and a molten solder plated layer formed on the conducting material. The conducting material includes a concave-convex conducting material that includes a concavity on top and under surfaces thereof, respectively, and a convexity on a side surface thereof, and that is formed by die processing a strip-shaped conducting material, and the molten solder plated layer comprises a flat surface formed by supplying a molten solder to the concavity of the concave-convex conducting material.

The present application is based on Japanese patent application Nos.2008-31658 and 2008-288813 filed Feb. 13, 2008 and Nov. 11, 2008, respectively, the entire contents of which are incorporated herein by reference.

### BACKGROUND OF THE INVENTION

1. Field of the Invention

This invention relates to a solar cell lead wire (i.e., a lead wire for a solar cell) that can effectively prevent cracking in a solar cell caused by a displacement of the lead wire.

2. Description of the Related Art

A polycrystal or single crystal Si cell is used for a semiconductor substrate of a solar cell. As shown in FIG. 4, a solar cell 101 is fabricated by joining solar cell lead wires 103 by soldering to predetermined regions of a semiconductor substrate 102. The solar cell lead wires 103 are joined to a front surface electrode 104 and a rear surface electrode 105 formed on the surface of the semiconductor substrate 102 by soldering. Electricity generated in the semiconductor substrate 102 is externally conducted through the solar cell lead wires 103.

As shown in FIG. 5, a conventional solar cell lead wire 111 includes a strip-shaped conducting material 112 and molten solder plated layers 113 formed on the top and under surfaces of the strip-shaped conducting material 112. The strip-shaped conducting material 112 is formed, for example, by applying a roll processing to a conducting material with a circular cross section so as to have a strip shape, and is also called as a rectangular conducting material or a rectangular wire.

The molten solder plated layer 113 is formed by supplying a molten solder on the top and under surfaces of the strip-shaped conducting material 112 by using a hot-dip plating method. The hot-dip plating method is a method including the steps of cleaning the top and under surfaces a, b of the strip-shaped conducting material 112 by using an acid cleaning and the like, and passing the strip-shaped conducting material 112 through a molten solder bath so as to laminate solder layers on the top and under surfaces a, b of the strip-shaped conducting material 112. As shown in FIG. 5, the molten solder plated layer 113 is formed to a mountain-like shape rising from the end portions to the central portion in the width direction due to an influence of the surface tension at the time that the molten solder is solidified.

The conventional lead wire 111 shown in FIG. 5 has the molten solder plated layer 113 expanding in a mountain-like shape on the top and under surfaces a, b of the strip-shaped conducting material 112. As explained in FIG. 4, when the solar cell lead wires 103 are joined by soldering to the front surface electrodes 104 of the semiconductor substrate 102, electrode strips (not shown) electrically communicating with the front surface electrodes 104 are preliminarily formed in the front surface electrodes 104. The molten solder plated layers 113 of the solar cell lead wires 103 are placed in contact with the electrode strips, and in this condition the soldering is carried out. Similarly, the solar cell lead wires 103 are joined to the rear surface electrodes los of the semiconductor substrate 102 by soldering.

Here, in the solar cell lead wires 111 (103) shown in FIG. 5, since the molten solder plated layer 113 is expanding in the central portion, the contact area between the electrode strip and the molten solder plated layer 113 is decreased. If the contact area between the electrode strip and the molten solder plated layer 113 is small, the heat conduction from the semiconductor substrate 102 to the molten solder plated layer 113 becomes insufficient so that defective soldering occurs.

Further, when the solar cell lead wires 111 are joined to both of the front and under surfaces of the semiconductor substrate 102, the small contact area between the electrode strip and the molten solder plated layer 113 may cause a displacement between the solar cell lead wire 111 joined to the front surface electrodes 104 by soldering and the solar cell lead wire 111 joined to the rear surface electrodes 105 by soldering, and due to the displacement the cell cracking (i.e., the clacking of the semiconductor substrate 102) occurs. Since the semiconductor substrate 102 is expensive, the cell cracking should be prevented.

In order to solve the problem that the contact area between the electrode strip and the molten solder plated layer is small, a method is proposed, where the molten solder plated layer is configured to have flat surfaces by forming a concavity on the top and under surfaces of the strip-shaped conducting material respectively and supplying a molten solder on the concavities (Patent Literature 1).

As shown in FIG. 6, the solar cell lead wires 121 described in the Patent Literature 1 uses an under concavity conducting material 123 which has the concavity 122 formed on the under surface b. The top surface a of the under concavity conducting material 123 is configured to be a flat surface or a convexity. As described above, when the under concavity conducting material 123 having the concavity 122 only on the under surface is passed through the molten solder bath, molten solder plated layers 124, 125 are formed on the top and under surfaces a, b of the under concavity conducting material 123. The molten solder plated layer 124 formed on the concavity 122 of the under concavity conducting material 123 is configured to have a flat surface. When the solar cell lead wire 121 is joined by soldering to the front and under surfaces of the semiconductor substrate at the flat under surface b of the molten solder plated layer 124, the solar cell lead wire 121 is strongly joined to the semiconductor substrate and the lead wire 121 becomes hard to separate from the semiconductor substrate, so that durability can be enhanced.

Patent Literature 1: WO-2004-105141

As described above, in order to join the solar cell lead wire to the semiconductor substrate, it is appropriate to form the molten solder plated layer so as to have a flat surface. However, according to the Patent Literature 1, in order to form the under surface of the strip-shaped conducting material so as to have the concavity, an appropriate plastic forming process or bending process is applied to the strip-shaped conducting material. For example, the concavity is formed by passing through a molding roll the strip-shaped conducting material. Further, when the strip-shaped conducting material is obtained by applying a slit processing to a tabular clad material, a bending process is applied by adjusting the interval between rotating cutter blades and the rotating speed. As described above, the under concavity conducting material 123 is obtained.

Since the plastic forming process and the bending process are an intermittent process, these processes are inferior in mass productivity. Further, when the strip-shaped conducting material is passed through the molding roll, it is difficult to adjust the pressure applied to the strip-shaped conducting material so that the under concavity conducting material is inferior in accuracy of the section size.

If the strip-shaped conducting material is formed to have the concavity by using the slit processing, burrs occur in the under concavity conducting material 123. If the burrs exist in the under concavity conducting material 123, when the solar cell lead wire 121 is joined to the semiconductor substrate, concentration of stress is caused at the portion where the burrs exist, so that the cell crack occurs in the semiconductor substrate.

Further, the solar cell lead wires 121 of the Patent Literature 1 electrically connect between a rear surface electrode of a first semiconductor substrate and a front surface electrode of a second semiconductor substrate, and between a rear surface electrode of a second semiconductor substrate and a front surface electrode of a third semiconductor substrate. As described above, the problem is not solved, that when the solar cell lead wires 121 are joined to both of the front and rear surfaces of the semiconductor substrate, displacements are caused between the solar cell lead wire 121 joined by soldering to the front surface electrode and the solar cell lead wire 121 joined by soldering to the rear surface electrode. The problem remains, that the cell crack occurs in the semiconductor substrate due to the displacements.

Since most of the solar cell cost is the semiconductor substrate cost. downsizing in thickness of the semiconductor substrate is investigated, but the semiconductor substrate downsized in thickness easily cracks. For example, if the thickness of the semiconductor substrate becomes not more than 200 μm, the percentage of the occurrence of the cell crack is increased. The downsizing in thickness of the semiconductor substrate cannot be expected in the situation that the cell crack occurs in the semiconductor substrate due to the solar cell lead wires

### SUMMARY OF THE INVENTION

Therefore, it is an object of the invention to provide a solar cell lead wire that can effectively prevent the cell cracking.

(1) According to one embodiment of the invention, a solar cell lead wire comprises:
a conducting material; and
a molten solder plated layer formed on the conducting material,
wherein the conducting material comprises a concave-convex conducting material that comprises a concavity on top and under surfaces thereof, respectively, and a convexity on a side surface thereof, and that is formed by die processing a strip-shaped conducting material, and
the molten solder plated layer comprises a flat surface formed by supplying a molten solder to the concavity of the concave-convex conducting material.

In the above embodiment (1), the following modifications and changes can be made.

(i) The molten solder plated layer comprises a flat surface formed on the top and under surfaces of the conducting material formed by supplying a molten solder to the concavity of the concave-convex conducting material.

(ii) The strip-shaped conducting material comprises a rectangular wire having a volume resistivity of not more than 50 μΩ.

(iii) The strip-shaped conducting material includes any one of Cu, Al, Ag, and Au.

(iv) The strip-shaped conducting material includes any one of a tough pitch Cu, a low-oxygen Cu, an oxygen-free Cu, a phosphorus deoxidized Cu and a high purity Cu with a purity of not less than 99.9999%.

(v) The molten solder plated layer includes a Sn based solder or a Sn based solder alloy including Sn as a first component and not less than 0.1% by weight of at least one element selected from Pb, In, Bi, Sb, Ag, Zn, Ni and Cu as a second component.

(2) According to another embodiment of the invention, a method of making a solar cell lead wire comprises:
forming a strip-shaped conducting material by applying a roll processing or a slit processing to a raw conducting material;
forming a concave-convex conducting material having a concavity on top and under surfaces thereof, respectively, and a convexity on a side surface thereof by applying a die processing to the strip-shaped conducting material;
heat-treating the concave-convex conducting material by using a continuous current heating furnace, a continuous heating furnace or a batch heating equipment; and
forming a molten solder plated layer so as to have a flat surface by supplying a molten solder to the concavity.

(3) According to another embodiment of the invention, a solar cell, comprises:
a semiconductor substrate comprising a front surface electrode and a rear surface electrode; and
the solar cell lead wire according to the above embodiment (1),
wherein the solar cell lead wire is joined to the front surface electrode and the rear surface electrode of the semiconductor substrate by soldering of the molten solder of the molten solder plated layer.

### BRIEF DESCRIPTION OF THE DRAWINGS

The preferred embodiments according to the invention will be explained below referring to the drawings, wherein:

FIG. 1A is a transverse cross-sectional view schematically showing a solar cell lead wire in one embodiment according to the invention;

FIG. 1B is a perspective view schematically showing a strip-shaped conducting material used as a material of the solar cell lead wire in one embodiment according to the invention;

FIG. 2 is a transverse cross-sectional view schematically showing a solar cell lead wire in another embodiment according to the invention;

FIG. 3A is a transverse cross-sectional view schematically showing a solar cell in one embodiment according to the invention;

FIG. 3B is a top view schematically showing the solar cell in one embodiment according to the invention;

FIG. 4A is a transverse cross-sectional view schematically showing a conventional solar cell;

FIG. 4B is a top view schematically showing the conventional solar cell;

FIG. 5 is a transverse cross-sectional view schematically showing a conventional solar cell lead wire;

FIG. 6 is a transverse cross-sectional view schematically showing a conventional solar cell lead wire (Patent Literature 1);

FIG. 7 is a perspective view schematically showing a drawing or extruding die used for fabricating the solar cell lead wire shown in FIG. 1; and

FIG. 8 is a perspective view schematically showing a drawing or extruding die used for fabricating the solar cell lead wire shown in FIG. 2.

### DETAILED DESCRIPTION OF THE PREFERRED EMBODIMENTS

The preferred embodiments according to the invention will be explained below referring to the drawings.

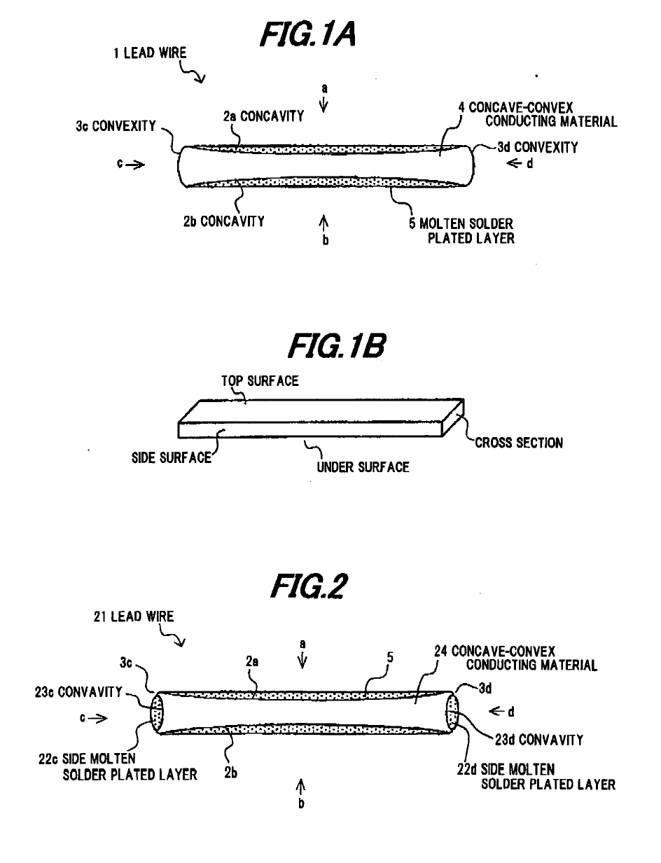

As shown in FIG. 1A, a solar cell lead wire 1 includes a concave-convex conducting material 4 which has concavities 2a, 2b on the top and under surfaces a, b and convexities 3c, 3d on the side surfaces c, d and which is formed by applying a drawing or extruding die processing to a strip-shaped conducting material shown in FIG. 1B, and a molten solder plated layer 5 which is configured to have flat surfaces by supplying a molten solder on the concavities 2a, 2b of the concave-convex conducting material 4 respectively.

As shown in FIG. 1B, the strip-shaped conducting material has flat side surfaces and top and under surfaces, and is configured to extend in the longitudinal direction. By applying the drawing or extruding die processing to the strip-shaped conducting material, the transverse cross-section is formed as shown in FIG. 1A. Further, the definitions of the terms of the top surface, the under surface, the side surface and the transverse cross-section are commonly used in the all drawings of the invention.

The concavities 2a, 2b are formed in order to house the molten solders.

The concavities 2a, 2b form such rounded concave curved surfaces between the side surfaces c, d that the concave-convex conducting material 4 is thick in thickness at the side surfaces c, d and thin in thickness at the central portion between the side surfaces c, d.

The convexities 3c, 3d form such rounded convex curved surfaces that the concave-convex conducting material 4 is short in width at the top and under surfaces a, b of the concave-convex conducting material 4 and long in width at the central portion between the top and under surfaces a, b of the concave-convex conducting material 4.

The molten solder plated layer 5 is homogeneous in width between the side surfaces c, d of the concave-convex conducting material 4. The top and under surfaces a, b of the molten solder plated layer 5 are formed to be flat surfaces.

The drawing or extruding die used for applying the drawing or extruding die processing to the strip-shaped conducting material so as to obtain the concave-convex conducting material 4 has a die hole which is formed to the same shape as that of the cross-section of the concave-convex conducting material 4 shown in FIG. 1. When the strip-shaped conducting material is passed through the die, the concave-convex conducting material 4 can be obtained which has the transverse cross-section having the same shape as that of the die hole.

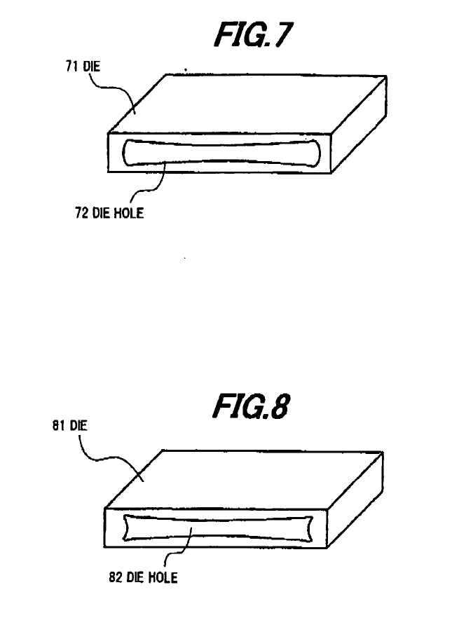

The die is shown in FIG. 7. As shown in the drawing, the die 71 has the die hole 72 formed so as to have the same cross-sectional shape as that of the concave-convex conducting material 4 shown in FIG. 1, where the die hole 72 are formed so as to have top and under edges having inward-directed convexities and the side edges having outward-directed convexities. When the long strip-shaped conducting material shown in FIG. 1B is continuously inserted to an opposite insertion opening of the die hole 72, the long concave-convex conducting material 4 can be continuously obtained from the die hole 72.

The solar cell lead wire 1 is configured to include the molten solder plated layer 5 formed so as to have a flat surface, in order that the solar cell lead wire 1 can be easily joined to the front and rear electrodes of the semiconductor substrate and the heat conduction needed at the joining process can be sufficiently ensured. By this, it is expected that the solar cell lead wires 1 are arranged in good order to the front and rear electrodes and a strong joining by soldering can be realized.

Further, the solar cell lead wire 1 is configured to include the side surface formed so as to have the convexities 3c, 3d, so that it is expected that the cell crack can be prevented. Furthermore, the prevention of the cell crack is not directly carried out by forming the convexities 3c, 3d in the side surfaces of the solar cell lead wire 1, but is carried out by reducing the stress applied to the semiconductor substrate at the joining process, due to that the convexities forced to exist are changed to flat surfaces by the existence of the concavities 2a, 2b to house the solder.

The strip-shaped conducting material includes, for example, a rectangular wire having a volume resistivity of not more than 50 μΩ. By applying the drawing or extruding die processing to the rectangular wire, the conducting materials shown in FIG. 1 and FIG. 2 described below can be obtained.

The strip-shaped conducting material includes any one of Cu, Al, Ag, and Au, or any one of a tough pitch Cu, a low-oxygen Cu, an oxygen-free Cu, a phosphorus deoxidized Cu and a high purity Cu (not less than 99.9999%).

The molten solder plated layer 5 includes a Sn based solder (a Sn based solder alloy). The Sn based solder (the Sn based solder alloy) uses Sn as a first component which is heaviest in weight of the components and contains not less than 0.1% of at least one element selected from the group consisting of Pb, In, Bi, Sb, Ag, Zn, Ni and Cu as a second component.

Hereinafter, advantages according to the invention will be explained.

When the solar cell lead wire 1 is joined by soldering to the front surface electrode and the rear surface electrode of the semiconductor substrate (not shown), the heating temperatures of the solar cell lead wire 1 and the semiconductor substrate are controlled to the temperature near the melting point of the solder of the molten solder plated layer 5. This is due to the fact that there is a large difference in the coefficient of thermal expansion between the concave-convex conducting material 4 (for example, Cu) of the solar cell lead wire 1 and the semiconductor substrate (Si). Due to the difference in the coefficient of thermal expansion, thermal stress occurs which causes crack generation in the semiconductor substrate. In order to reduce the stress, it is preferable to carry out a low temperature joining. Therefore, the heating temperatures of the solar cell lead wire 1 and the semiconductor substrate are controlled to the temperature near the melting point of the solder of the molten solder plated layer 5.

The heating method at the above-mentioned joining includes a method where two applications of heating are combined, one is to be heated from a hot plate on which the semiconductor substrate is placed, and another is to be heated from the upper portion of the solar cell lead wire 1 disposed on the semiconductor substrate.

In order to increase the beat conduction satisfactorily from the semiconductor substrate to the molten solder plated layer 5 by increasing the contact area between the front surface electrode and the rear surface electrode of the semiconductor substrate and the molten solder plated layer 5 or a conductive paste layer (a joining layer), it is preferable that the solar cell lead wire 1 including the molten solder plated layer 5 is configured to have a rectangular shape and to have flat top and under surfaces with which the front surface electrode and the rear surface electrode of the semiconductor substrate contact.

However, the conventional solar cell lead wire 111 shown in FIG. 5 is formed to a mountain-like shape rising in the central portion of longer direction, and at the joining by soldering to the front surface electrode and the rear surface electrode of the semiconductor substrate, the contact area is small between the front surface electrode and the rear surface electrode of the semiconductor substrate and the molten solder plated layer 5 of the solar cell lead wires 111. Therefore, the heat conduction becomes insufficient, and the solar cell lead wire 111 is unequally located on the front surface electrode and the rear surface electrode so that displacements of the solar cell lead wire 111 to the front surface electrode and the rear surface electrode of the semiconductor substrate are caused, and due to this and the like the cell crack occurs.

According to the invention, the molten solder plated layer 5 which defines the side surfaces of the solar cell lead wire 1 is configured to have flat top and under surfaces so that the above-mentioned conventional problem can be solved.

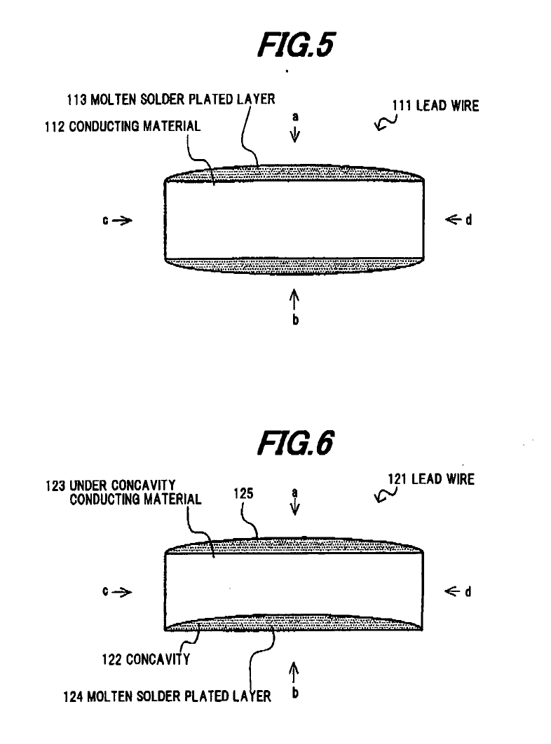

In case of the solar cell lead wires 121 of Patent Literature 1 shown in FIG. 6, the concavity 122 of the under concavity conducting material 123 houses the molten solder so that the molten solder plated layer 124 is configured to have a flat surface. However, when the strip-shaped conducting material is formed to the under concavity conducting material 123 by using the slit processing, burrs occur in the under concavity conducting material 123. Due to the occurrence of the burrs, concentration of stress is caused at the joining portion between the solar cell lead wires 121 and the under concavity conducting material 123, so that the cell crack occurs.

Further, with regard to the under concavity conducting material 123 used for the solar cell lead wires 121 disclosed in Patent Literature 1, only the under surface b has a concavity and the top surface a is a flat surface. When the molten solder plated layers 124, 125 are formed on the under concavity conducting material 123, the under surface b of the molten solder plated layer 124 becomes flat but the top surface a of the molten solder plated layer 125 expands so as to have a mountain-like shape. That is, the solar cell lead wires 121 disclosed in Patent Literature 1 has the under surface b which is flat and the top surface a which expands so as to have a mountain-like shape. When the solar cell lead wires 121 are joined to both of the front and under surfaces of the semiconductor substrate, displacements of the solar cell lead wire 121 to the front and under surfaces are caused. Due to the displacements the cell crack occurs in the semiconductor substrate.

Hereinafter, the reason why the cell crack occurs will be explained.

Joining of a rectangular wire as the strip-shaped conducting material to the semiconductor substrate is carried out by sandwiching and heating the rectangular wire and the semiconductor substrates so as to adapt the rectangular wire to the joining portions (the front surface electrodes and the rear surface electrodes) at a predetermined pressure. At this time, if the burrs exist in the rectangular wire, duet to the burrs, high pressure occurs to the semiconductor substrates so that the cell crack occurs. If the burrs do not exist, pressure applied to the semiconductor substrates from the rectangular wire at the joining becomes low so that the cell crack does not occur. Further, if the rectangular wire which has the joining surface expanding in a mountain-like shape is joined to the semiconductor substrates, displacements of the rectangular wires on the front surface electrode and the rear surface electrode are easily caused. Due to the displacements, the rectangular wire is alternately sandwiched by the front surface and the rear surface of the semiconductor substrate so that the cell crack occurs. If the rectangular wire which has the joining surface being flat is joined to the semiconductor substrates, displacements of the rectangular wires on the front surface electrode and the rear surface electrode are not easily caused. If displacements are not caused, the rectangular wire is sandwiched at almost the same location by the front surface and the rear surface of the semiconductor substrate and the stress to the semiconductor substrate is reduced so that the cell crack does not occur.

In this regard, the concave-convex conducting material 4 of the solar cell lead wire 1 according to the invention is formed by applying the drawing or extruding die processing to the strip-shaped conducting material so that the concave-convex conducting material 4 can be configured to have concavities 2a, 2b on the top and under surfaces and convexities 3c, 3d on the side surfaces. The convexities 3c, 3d are formed to curved surfaces. The front and rear surfaces a, b of the molten solder plated layer 5 are formed to flat surfaces. Due to the above, the burrs do not exist, the joining surface to the semiconductor substrate becomes flat. Therefore, the cell crack is prevented.

As a method of fabricating the convexity of the joining surface to the curved surface, a chamfer by cutting can be also used.

Further, according to the invention, since the concave-convex conducting material 4 is formed so as to have the same traverse cross-section as that of a die hole by using the drawing or extruding die processing that the strip-shaped conducting material is passed through a die having the die hole which has the same cross-section as that of the concave-convex conducting material 4, the concave-convex conducting material 4 is excellent in dimension stability and mass productivity. As a result, the invention can provide a solar cell lead wire that is capable of remarkably preventing the cell crack.

Further, according to the invention, since the molten solder plated layer 5 is formed so as to have flat surfaces by forming the concavities 2a, 2b on the top and under surfaces a, b of the concave-convex conducting material 4 and supplying the molten solder in the concavities 2a, 2b, the solar cell lead wire 1 is configured to have the top and under surfaces a, b which are flat. Therefore, in case of joining the solar cell lead wire 1 to the both front and rear surfaces of the semiconductor substrate, displacements are not caused between the solar cell lead wire 1 joined by soldering to the front surface electrodes and the solar cell lead wire 1 joined by soldering to the rear surface electrodes.

Furthermore, according to the invention, since the concavities 2a, 2b are formed on the top and under surfaces a, b of the concave-convex conducting material 4, there is also the possibility of forming solder fillets which are formed on the surface electrodes of the Si cell after joining of the lead wires so as to have a stable mountain-like shape. The fillet means wax or solder leaked from the spaces of joints where a brazing or soldering process is carried out.

TABLE 1

| Material | Cu | Ag | Au | Al |
|---|---|---|---|---|
| Coefficient of thermal | 17.0 | 19.1 | 29.0 | 23.5 |
| expansion | | | | |
| (×10⁻⁶/° C.) | | | | |
| 0.2% Proof stress | 40 | 55 | 30 | 20 |
| (MPa) | | | | |
| Volume resistivity | 16.9 | 16.3 | 22.0 | 26.7 |
| (μΩ · mm) | | | | |

It is preferable that the strip-shaped conducting material has a relatively low volume resistivity. As shown in Table 1, the strip-shaped conducting material is of Cu, Al, Ag, and Au. Ag has the lowest volume resistivity of Cu, Al, Ag, and Au. Therefore, if Ag is used as the strip-shaped conducting material, power generation efficiency of solar cell using the lead wire 1 can be maximized. If Cu is used as the strip-shaped conducting material, the solar cell lead wire 1 can be obtained in low-cost. If Al is used as the strip-shaped conducting material, the solar cell lead wire 1 can be reduced in weight.

If Cu is used as the strip-shaped conducting material, any one of a tough pitch Cu, a low-oxygen Cu, an oxygen-free Cu, a phosphorus deoxidized Cu and a high purity Cu (not less than 99.9999%) can be used as the above-mentioned Cu. In order to reduce 0.2% proof stress of the strip-shaped conducting material to the smallest, it is advantageous to use Cu being of high purity. Therefore, if the high purity Cu (not less than 99.9999%) is used, the 0.2% proof stress of the strip-shaped conducting material can be reduced. If the tough pitch Cu or the phosphorus deoxidized Cu is used, the solar cell lead wire 1 can be obtained at low cost.

Solder used for the molten solder plated layer 5 includes a Sn based solder or a Sn based solder alloy using Sn as a first component and containing not less than 0.1% of at least one element selected from the group consisting of Pb, In, Bi, Sb, Ag, Zn, Ni and Cu as a second component. The solder can contain not more than 1000 ppm of microelements as a third component.

The concavities 2a, 2b of the concave-convex conducting material 4 can be thinly coated by metallic materials which includes Sn as a first component and at least one element selected from the group consisting of Ni, Ag, Zn, Cr, Cu, Au, Pd, In, Bi, Sb, Ru, and Pt as a second component (not more than 1000 ppm of microelements can be contained as a third component), instead of forming the molten solder plated layer 5 so as to have flat surfaces by coating solder plating on the concavities 2a, 2b of the concave-convex conducting material 4. When or before the solar cell lead wire 1 is joined to the semiconductor substrate, it can be also used that an electrically conductive adhesive is coated on the concavities 2a, 2b thinly coated by the metallic materials and the solar cell lead wire 1 is bonded to the front surface electrode and the rear surface electrode of semiconductor substrate.

Hereinafter, a solar cell lead wire in another embodiment according to the invention will be explained.

As shown in FIG. 2, a solar cell lead wire 21 includes, in addition to the solar cell lead wire 1 shown in FIG. 1, a concave-convex conducting material 24 which has concavities 23c, 23d formed on the convexities 3c, 3d on the side surfaces c, d, and side molten solder plated layers 22c, 22d which are formed by supplying molten solder on the concavities 23c, 23d of the concave-convex conducting material 24 respectively.

If the side molten solder plated layers 22c, 22d are formed on the convexities 3c, 3d on the side surfaces c, d of the concave-convex conducting material 24, the solder contributing to joining between the concave-convex conducting material 24 and the semiconductor substrate can be sufficiently supplied to the joining portion between the front surface electrode and the under surface electrode, so that good fillets can be obtained which have a cross-section shaped like a mountain. Due to this, the solar cell lead wire 21 can be obtained which is excellent in joining reliability (conductivity, joining strength and the like).

FIG. 8 shows a drawing or extruding die used for fabricating the concave-convex conducting material 24 shown in FIG. 2. As shown in the drawing, the die 81 has the die hole 82 which is formed so as to have the same cross-sectional shape as that of the concave-convex conducting material 24 shown in FIG. 2, where the die hole 82 arc formed so as to have top and under edges having inward-directed convexities, and the side edges having outward-directed convexities at the top and under portions and a concavity at the central portion. When the long strip-shaped conducting material shown in FIG. 1B is continuously inserted to an opposite insertion opening of the die hole 82, the long concave-convex conducting material 24 can be continuously obtained from the die hole 82.

Hereinafter, a method of fabricating the solar cell lead wire according to the invention will be explained.

First, a strip-shaped conducting material is formed by applying a roll processing or a slit processing to a raw conducting material (not shown). A concave-convex conducting material 4 is formed, which has a concavity on the top and under surfaces thereof respectively and a convexity on the side surfaces thereof respectively by applying a drawing or extruding die processing to the strip-shaped conducting material. The concave-convex conducting material is heat-treated by using a continuous current heating furnace, a continuous heating furnace or a batch heating equipment. And then, a molten solder plated layer 5 is formed so as to have flat surfaces by supplying a molten solder on the concavities 2a, 2b.

Generally, at the inside of solid or liquid, intermolecular force operates between internal molecules so that a behavior of becoming reduced in size as much as possible is recognized. Since molecules located to the surface portion are surrounded by different molecules at the one side, they are in a high internal energy state, and attempt to transform the excess energy state to a stable energy state. In case of solder (liquid) making contact with air, since intermolecular force in the air is extremely small in comparison with that in the solder, the molecules located in the surface portion of the solder side are not pulled from the molecules located in the air side, but are pulled only from the molecules located in the internal portion of the solider side. Therefore, the molecules located in the surface portion of the solder side always attempt to enter into the solder so that the surface of the solder attempts to have a spherical shape which has the smallest surface area (or which contains the least amount of the elements constituting the solder).

Due to this force which operates to reduce the surface area, in other words, due to surface tension, a conventional solar cell lead wire 111 shown in FIG. 5, includes molten solder plated layers 113 coagulated in a shape of expanding like a mountain, which are formed on the top and under surfaces a, b of the strip-shaped conducting material 112. The reason why the solder, which is supposed to have a spherical shape, does not have the spherical shape is that an interacting force of an interface between the solder and the strip-shaped conducting material 112 (an interface tension between the solder and the strip-shaped conducting material 112) is applied to the solder.

On the other hand, since the solar cell lead wire 1 according to the invention includes the concave-convex conducting material 4 which has a large surface area contacting the solder, the interface tension between the solder and the concave-convex conducting material 4 becomes large and the solder changes in shape more significantly from the spherical shape, so that the molten solder plated layer 5 can be formed so as to have flat surfaces when the solder is coagulated.

A method of fabricating the raw conducting material to the strip-shaped conducting material includes a roll processing and a slit processing. The rolling processing means a process of rolling round wires through rolls so as to obtain rectangular wires. If the strip-shaped conducting material is formed by using the roll processing, the strip-shaped conducting material which is long and homogeneous in width in the longitudinal direction can be obtained. The slit processing can respond to the raw conducting materials which have various widths. Namely, by using the slit processing, even if the raw conducting materials do not have homogeneous widths in the longitudinal direction or even if various raw conducting materials having different widths are used, the raw conducting materials which are long and homogeneous in width in the longitudinal direction can be obtained.

A method of fabricating the strip-shaped conducting material to the concave-convex conducting material 4 includes a cutting process that continuously cuts the burrs other than the drawing or extruding die processing.

By heat-treating the concave-convex conducting material 4, the softening characteristic thereof can be enhanced. It is effective in reducing the 0.2% proof stress to enhance the softening characteristic of the concave-convex conducting material 4. The heat-treating method includes a continuous current heating, a continuous heating and a batch heating. If the heat-treating is carried out continuously and longwise it is preferable to use the continuous current heating. If a stable heat-treating is needed, it is preferable to use the batch heating. In terms of preventing oxidation it is preferable to use a furnace of hydrogen reduction atmosphere.

The furnace of hydrogen reduction atmosphere includes a continuous current heating furnace, a continuous heating furnace and a batch heating equipment.

Hereinafter, a solar cell according to the invention will be explained.

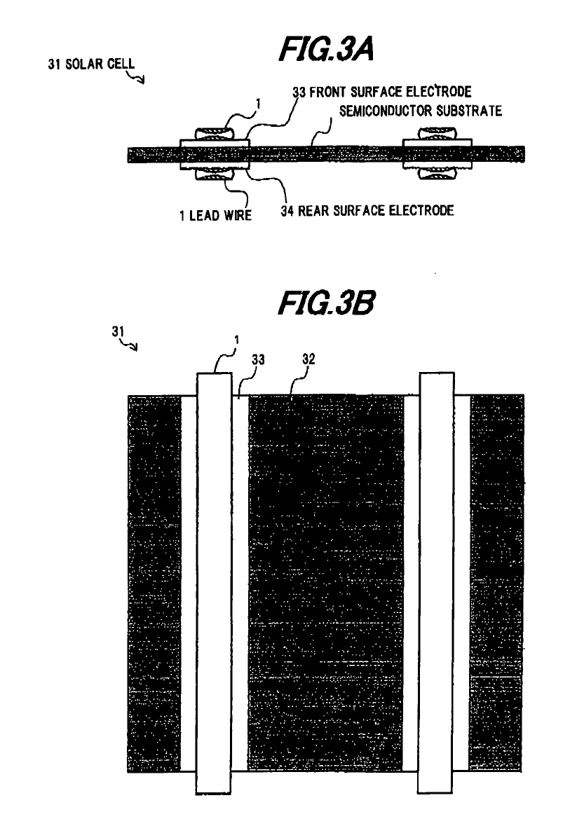

As shown in FIGS. 3A and 3B, a solar cell 31 according to the invention includes a semiconductor substrate 32 having a front surface electrode 33 and a rear surface electrode 34 and the solar cell lead wire 1 or 21 as described above, wherein the solar cell lead wire 1 or 21 is joined by soldering to the front surface electrode 33 and the rear surface electrode 34 of the semiconductor substrate 32 by using the solder of the molten solder plated layer 5.

The molten solder plated layers 5 to form joining surfaces between the solar cell lead wires 1 and the front surface electrode 33 and the rear surface electrode 34 have flat surfaces, so that the solar cell lead wires 1 are stably located to the front surface electrode 33 and the rear surface electrode 34 and are prevented from displacements.

According to the solar cell 31 of the invention, joining strength between the solar cell lead wire 1 and the semiconductor substrate is high and the cell crack can be prevented, so that the yield of the solar cell can be enhanced.

### EXAMPLES

### Example 1

A strip-shaped conducting material which has a rectangular wire-like shape of 2.0 mm in width and 0.16 mm in thickness was formed by applying a roll processing to a Cu material as a raw conducting material. A concave-convex conducting material 4 having concavities 2a, 2b was formed by applying a drawing or extruding die processing to the strip-shaped conducting material. The concave-convex conducting material 4 was heat-treated by using a batch heating equipment; and molten solder plated layers were formed on the concavities 2a, 2b of the concave-convex conducting material 4 so as to have flat surfaces by coating with solder plating of Sn-3% Ag-0.5Cu around the strip-shaped conducting material 4 (the heat-treated Cu was used as the conducting body). From the above, the solar cell lead wire 1 shown in FIG. 1 was obtained.

### Example 2

In addition to the composition of the solar cell lead wire 1 of Example 1, the side molten solder plated layers 22c, 22d were formed on the convexities 3c, 3d on the side surfaces c, d, and the solar cell lead wire 21 shown in FIG. 2 was obtained.

### Example 3

A strip-shaped conducting material which has a rectangular wire-like shape of 2.0 mm in width and 0.16 mm in thickness was formed by applying a slit processing to a Cu-invar-Cu material (ratio of 2:1:2) as a raw conducting material. A concave-convex conducting material 4 having concavities 2a, 2b was formed by applying a drawing or extruding die processing to the strip-shaped conducting material. Molten solder plated layers were formed on the concavities 2a, 2b of the concave-convex conducting material 4 so as to have flat surfaces by coating with solder plating around the strip-shaped conducting material 4. From the above, the solar cell lead wire 1 shown in FIG. 1 was obtained.

### Comparative Example 1

A strip-shaped conducting material 112 which has a rectangular wire-like shape of 2.0 mm in width and 0.16 mm in thickness was formed by applying a roll processing to a Cu material as a raw conducting material. The strip-shaped conducting material 112 was heat-treated by using a batch heating equipment, and molten solder plated layers 113 expanding in a mountain-like shape were formed on the flat top and under surfaces of the strip-shaped conducting material 112 by coating with solder plating around the strip-shaped conducting material 112 (the heat-treated Cu was used as the conducting body). From the above, the solar cell lead wire 111 shown in FIG. 5 was obtained.

### Comparative Example 2

An under concavity conducting material 123 of 2.0 mm in width and 0.16 mm in thickness was formed by applying a slit processing to a Cu-invar-Cu material (ratio of 2:1:2) as a raw conducting material. A molten solder plated layer 124 having flat surface was formed on the concavity 122 of the under concavity conducting material 123, and the molten solder plated layer 125 expanding in a mountain-like shape was formed on the flat surface of the under concavity conducting material 123 by by coating with solder plating around the under concavity conducting material 123. From the above, the solar cell lead wire 121 shown in FIG. 6 was obtained.

As a result of observation of the cross-sections of the solar cell lead wires of Examples 1, 2 and 3, and Comparative Examples 1 and 2, it was confirmed that in cases of Examples 1, 2 and 3 each of the top and under surfaces a, b to be joined to the semiconductor substrate has a flat shape on the cross-section. In case of Comparative Example 1 each of the top and under surfaces a, b to be joined to the semiconductor substrate has a mountain-like shape expanding in the central portion on the cross-section. In case of Comparative Example 2 the under surface b to be joined to the semiconductor substrate has a flat shape on the cross-section and the top surface a to be joined to the semiconductor substrate has a mountain-like shape expanding in the central portion on the cross-section.

The solar cell lead wires in Examples 1, 2 and 3, and Comparative Examples 1 and 2 were coated with an appropriate amount of rosin based flux, and each of the solar cell lead wires was disposed on a Cu plate, and it was heated on a hot plate (kept at 260 degrees C., for 30 seconds), so that the solar cell lead wire was joined by soldering to the Cu plate. Further, in order to evaluate the joining forces of the solar cell lead wires to the Cu plate, the lead wires being joined by soldering to the Cu plates, 90° peel test was carried out. And, the solar cell lead wires were installed in the electrode sites on both surfaces of the semiconductor substrate (Si cell) of 150 mm by 150 mm in size and 180 μm in thickness, and they were similarly heated on the hot plate in a state that a weight of 10 g is mounted (kept at 260 degrees C., for 30 seconds), so that they were joined by soldering. The cell crack occurrence at the joining by soldering was examined. With regard to Comparative Example 2, two cases were carried out that the top surface a is joined and the under surface b is joined, and the cell crack occurrence was examined about each of the two cases.

The evaluation results of Examples 1, 2 and 3, and Comparative Examples 1 and 2 are shown in Table 2.

TABLE 2

| | | | Cross | Material | | |
|---|---|---|---|---|---|---|
| | Conductor | Die | section | of joining | Joining | Cell |
| | processing | processing | shape | layer | force | breaking |
| Example 1 | Roll | Yes | FIG. 1 | Solder | ◯ | ◯ |
| Example 2 | Roll | Yes | FIG. 2 | Solder | ⊚ | ◯ |
| Example 3 | Slit | Yes | FIG. 1 | Solder | ◯ | ◯ |
| Comparative | Roll | No | FIG. 5 | Solder | Δ | Δ |
| Example 1 | | | | | | |
| Comparative | Slit | No | FIG. 6 | Solder | ◯ | X |
| Example 2 | | | | | (Under | (Under |
| | | | | | surface b) | surface b) |
| | | | | | Δ | ◯ |
| | | | | | (Top | (Top |
| | | | | | surface a) | surface a) |

The column of “Conductor processing” in Table 2 shows that a fabricating method for forming a strip-shaped conducting material having a rectangular wire-like shape from a raw conducting material. The column of “Die processing” shows whether the die processing described in the invention was used (yes) or not (no). The column of “Cross-section shape” shows the drawings in which the cross-section shapes are shown. The column of “Joining force” shows a test result that when the solar cell lead wire and the Cu plate are pulled by the 90° peel test, how large the tensile (pulled) force was at the separation of joining between the solar cell lead wire and the Cu plate, ⊚ shows that the tensile force was not less than 20 N, ◯ shows that the tensile force was 10 N to 20 N, and Δ shows that the tensile force was not more than 10 N. The column of “Cell crack” shows that when it was examined by the test of joining by soldering, if the cell crack to be visually confirmed was found at one site or more sites, it is judged that there is the cell crack, and in case of other than the above, it is judged that there is no cell crack, and ◯ shows that the ratio of having no cell cracking in all the joining portions was not less than 90%, Δ shows that the ratio of having no cell cracking was not less than 70% and less than 90%, and × shows that the ratio of having no cell cracking was less than 70%. The ratio of having no cell cracking was calculated from the following formula.

(the ratio of having no cell cracking)=[(the number of cells where no cracking occurred)/(the number of cells for which the solder joining test was carried out)]×100

As shown in Table 2, it was confirmed that the solar cell lead wires in Examples 1, 2 and 3 have excellent joining force, due to the fact that the concave-convex conducting material 4 having concavities 2a, 2b on the top and under surfaces a, b and convexities 3c, 3d on the side surfaces was formed by applying the drawing or extruding die processing, and the molten solder plated layers 5 were formed so as to have flat surfaces by supplying the molten solder on the concavities 3c, 3d.

Particularly, in case of the solar cell lead wire 21 of Example 2, the molten solder plated layers 5 were formed so as to have flat surfaces by supplying the molten solder in the concavities 2a, 2b of the top and under surfaces a, b, and then the solder contributing to joining can be sufficiently supplied, so that good fillets could be formed and sequentially high joining force could be obtained.

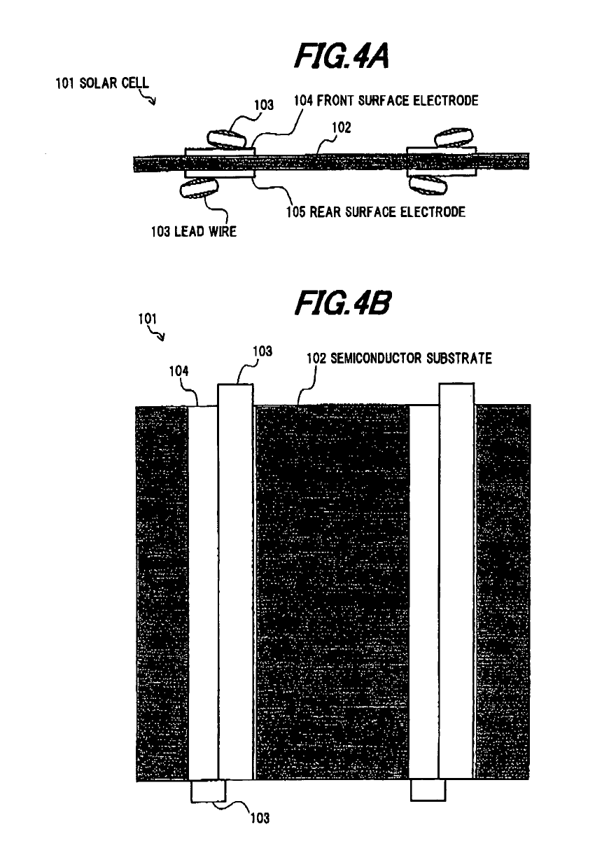

In case of the solar cell lead wire 21 of Example 2, the joining surface to the semiconductor substrate is flat, so that area contacts shown in the solar cells of the invention (FIG. 3) can be used, instead of point contacts shown in the conventional solar cells (FIG. 4), further, concavities 23c, 23d are formed on the convexities 3c, 3d on the side surfaces c, d, and side molten solder plated layers 22c, 22d which are formed by supplying molten solder on the concavities 23c, 23d, so that the solder contributing to joining can be increased and good fillets can be formed. Due to this, the joining properties (strength and conductivity) can be enhanced.

Further, as shown in Table 2, the solar cell lead wire 1, 21 includes the concave-convex conducting material 4 which has concavities 2a, 2b on the top and under surfaces a, b and convexities 3c, 3d on the side surfaces, and the molten solder plated layer 5 which is formed to have flat surfaces by supplying the molten solder on the concavities 2a, 2b, so that it was confirmed that the cell crack can be prevented.

On the other hand, in case of Comparative Example 1 where the roll processing and the die processing are not carried out, although the cell crack is not found, the joining force is somewhat inferior to the invention. In case of Comparative Example 2 where the slit processing is carried out but the die processing is not carried out, if the surface b being flat is used as the joining surface, although the joining force is excellent, the cell crack is found. If the surface a expanding in the central portion is used as the joining surface, although the cell crack is not found, the joining force is somewhat inferior to the invention.

As described above, from the evaluation result of Examples 1, 2 and 3, and Comparative Examples 1 and 2, it was confirmed that the solar cell lead wire according to the invention can highly prevent the cell crack.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A solar cell lead wire, comprising:
a conducting material; and
a molten solder plated layer formed on the conducting material,
wherein the conducting material comprises a concave-convex conducting material that comprises a concavity on top and under surfaces thereof, respectively, and a convexity on a side surface thereof, and that is formed by die processing a strip-shaped conducting material, and
the molten solder plated layer comprises a flat surface formed by supplying a molten solder to the concavity of the concave-convex conducting material.

2. The solar cell lead wire according to claim 1, wherein the molten solder plated layer comprises a flat surface formed on the top and under surfaces of the conducting material formed by supplying a molten solder to the concavity of the concave-convex conducting material.

3. The solar cell lead wire according to claim 1, wherein the strip-shaped conducting material comprises a rectangular wire having a volume resistivity of not more than 50 μΩ.

4. The solar cell lead wire according to claim 1, wherein the strip-shaped conducting material includes any one of Cu, Al, Ag, and Au.

5. The solar cell lead wire according to claim 1, wherein the strip-shaped conducting material includes any one of a tough pitch Cu, a low-oxygen Cu, an oxygen-free Cu, a phosphorus deoxidized Cu and a high purity Cu with a purity of not less than 99.9999%.

6. The solar cell lead wire according to claim 1, wherein the molten solder plated layer includes a Sn based solder or a Sn based solder alloy including Sn as a first component and not less than 0.1% by weight of at least one element selected from Pb, In, Bi, Sb, Ag, Zn, Ni and Cu as a second component.

7. A method of making a solar cell lead wire, comprising:
forming a strip-shaped conducting material by applying a roll processing or a slit processing to a raw conducting material;
forming a concave-convex conducting material having a concavity on top and under surfaces thereof, respectively, and a convexity on a side surface thereof by applying a die processing to the strip-shaped conducting material;
heat-treating the concave-convex conducting material by using a continuous current heating furnace, a continuous heating furnace or a batch heating equipment; and
forming a molten solder plated layer so as to have a flat surface by supplying a molten solder to the concavity.

8. A solar cell, comprising:
a semiconductor substrate comprising a front surface electrode and a rear surface electrode; and
the solar cell lead wire according to claim 1,
wherein the solar cell lead wire is joined to the front surface electrode and the rear surface electrode of the semiconductor substrate by soldering of the molten solder of the molten solder plated layer.
